(19) United States
(12) Patent Application Publication
(10) Pub. No.: US 2010/0207192 A1
(43) Pub. Date: Aug. 19, 2010

(54) NON-VOLATILE SEMICONDUCTOR MEMORY DEVICE AND MANUFACTURING METHOD THEREOF

(75) Inventors: Toshiya UENISHI, Tokyo (JP); Yasufumi Morimoto, Itami (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 12/698,517

(22) Filed: Feb. 2, 2010

(30) Foreign Application Priority Data
Feb. 13, 2009 (JP) 2009-031363

(51) Int. Cl. H01L 29/792; H01L 21/28

(52) U.S. Cl. 257/324; 438/591; 257/E29.309; 257/E21.21

(57) ABSTRACT

A non-volatile semiconductor memory device capable of more efficiently trapping charges in a charge storage layer without increasing the thickness of the charge storage layer, as well as a manufacturing method thereof. In the non-volatile semiconductor memory device a tunnel insulating film, a charge storage layer, a block insulating film, and a gate electrode are disposed successively between a first source/drain region and a second source/drain region above a semiconductor substrate. The charge storage layer has a first layer and second layers, the first layer has a first nitrogen atom concentration, each of the second layers has a second nitrogen atom concentration, higher than the first nitrogen atom concentration and faces one of the tunnel insulating film and the block insulator.

### CROSS-REFERENCE TO RELATED APPLICATIONS

The disclosure of Japanese Patent Application No. 2009-31363 filed on Feb. 13, 2009 including the specification, drawings and abstract is incorporated herein by reference in its entirety.

### BACKGROUND OF THE INVENTION

The present invention concerns a non-volatile semiconductor memory device and a manufacturing method thereof and it particularly relates to a non-volatile semiconductor memory device having a charge storage layer and a manufacturing method thereof.

A non-volatile semiconductor memory device includes an MONOS (Metal-Oxide-Nitride-Oxide-Semiconductor) type or an SONOS (Semiconductor-Oxide-Nitride-Oxide-Semiconductor) type memory device. For example, according to Japanese Unexamined Patent Publication No. Hei 07 (1995)-142614 (hereinafter referred to as a Patent Document 1), the memory device includes a semiconductor substrate, a gate electrode, and a memory gate insulating film. The memory gate insulating film includes a tunnel film comprising an oxynitride film, a memory nitride film, and a top insulating film comprising an oxynitride film. The writing operation of the memory device is conducted by storing electrons in the nitride film.

### SUMMARY OF THE INVENTION

The amount of charges stored in the nitride film (charge storage layer) decreases little by little with lapse of time. That is, along with the time, a threshold voltage approaches a state before writing. Accordingly, when the time passes exceeding the data retention life time, written information is lost. For extending the data retention life time, the amount of the threshold voltage that changes by writing may be increased. For this purpose, it is necessary to increase the amount of charges that can be trapped per unit area of the charge storage layer, that is, the density of trapped charges.

A simple method of increasing the density of the trapped charges includes a method of increasing the thickness of the charge storage layer. In this case, however, since the electric field applied to the charge storage layer is lowered along with increase of the film thickness, it results in a problem of lowering the writing speed. Further, increase of the writing voltage in order not to lower the electric field results in a problem that this is not only contrary to the requirement of lowering the voltage in the non-volatile semiconductor memory device, but also increases the progress of deterioration by rewriting. Accordingly, it is not preferred to increase the thickness of the charge storage layer.

Therefore, the present invention intends to provide a semiconductor memory device capable of trapping charges more efficiently in the charge storage layer without increasing the thickness of the charge storage layer.

A non-volatile semiconductor memory device in an embodiment of the present invention includes a semiconductor substrate, first and second source/drain regions, a tunnel insulating film, a charge storage layer, a block insulating film, and a gate electrode. The first and the second source/drain regions are disposed being spaced from each other over the semiconductor substrate. The tunnel insulating film, the charge storage layer, the block insulating film, and the gate electrode are disposed successively between the first and the second source/drain regions over the semiconductor substrate. The charge storage layer includes a first layer having a first nitrogen atom concentration and a second layer having a second nitrogen atom concentration higher than the first nitrogen atom concentration. The second layer faces one of the tunnel insulating film and the block insulating film.

According to the first embodiment described above, the second layer of the charge storage layer has a second nitrogen atom concentration higher than the first nitrogen atom concentration and faces one of the tunnel insulating film and the block insulating film. Accordingly, the charge storage layer has a second nitrogen atom concentration higher than the first nitrogen atom concentration near the boundary with one of the tunnel insulating film and the block insulating film. As a result, charge can be trapped more efficiently to the charge storage layer without increasing the thickness of the charge storage layer.

### BRIEF DESCRIPTION OF THE DRAWINGS

FIG. 1 is a fragmentary cross sectional view schematically showing the configuration of a non-volatile semiconductor memory device in a first embodiment of the invention;

FIG. 2 is a fragmentary cross sectional view schematically showing a first step for the method of manufacturing a non-volatile semiconductor memory device in the first embodiment of the invention;

FIG. 3 is a fragmentary cross sectional view schematically showing a second step for the method of manufacturing a non-volatile semiconductor memory device in the first embodiment of the invention;

FIG. 4 is a fragmentary cross sectional view schematically showing a third step for the method of manufacturing a non-volatile semiconductor memory device in the first embodiment of the invention;

FIG. 5 is a fragmentary cross sectional view schematically showing a fourth step for the method of manufacturing a non-volatile semiconductor memory device in the first embodiment of the invention;

FIG. 6 is a fragmentary cross sectional view schematically showing a fifth step for the method of manufacturing a non-volatile semiconductor memory device in the first embodiment of the invention;

FIG. 7 is a fragmentary cross sectional view schematically showing a first step for a method of manufacturing a non-volatile semiconductor memory device in a comparative example;

FIG. 8 is a fragmentary cross sectional view schematically showing a second step for a method of manufacturing a non-volatile semiconductor memory device in a comparative example;

FIG. 9 is a fragmentary cross sectional view schematically showing the configuration of a non-volatile semiconductor memory device of the comparative embodiment;

FIG. 10 is a fragmentary cross sectional view schematically showing the configuration of a non-volatile semiconductor memory device in a second embodiment of the invention;

FIG. 11 is a graph showing a relationship between a writing time and a threshold voltage of a non-volatile semiconductor memory device in a second embodiment of the invention;

FIG. 12 is a graph showing a relation between a writing time and a threshold voltage of a non-volatile semiconductor memory device of the comparative example;

FIG. 13 is a fragmentary cross sectional view schematically showing the configuration of a non-volatile semiconductor memory device in a third embodiment of the invention;

FIG. 14 is a graph showing a relationship between a writing time and a threshold voltage of a non-volatile semiconductor memory device in a third embodiment of the invention;

FIG. 15 is a graph showing a relation between a writing time and a threshold voltage of a non-volatile semiconductor memory device of a comparative example; and

FIG. 16 is a fragmentary cross sectional view schematically showing the configuration of a non-volatile semiconductor memory device in a fourth embodiment of the invention.

### DETAILED DESCRIPTION OF THE PREFERRED EMBODIMENTS

Preferred embodiments of the present invention are to be described with reference to the drawings.

### First Embodiment

At first, description is to be made to the configuration of a non-volatile semiconductor memory device in this embodiment.

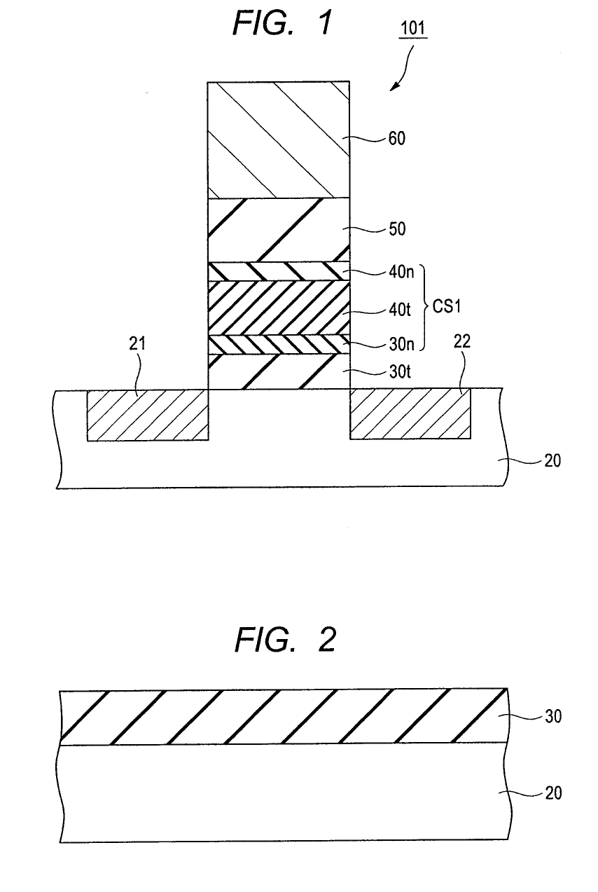

Referring to FIG. 1, a non-volatile semiconductor memory device 101 has a silicon substrate (semiconductor substrate) 20, first and second source/drain regions 21 and 22, a tunnel insulating film 30t, a charge storage layer CS1, a block insulating film 50, and a gate electrode 60.

The first and the second source/drain regions 21 and 22 are disposed being spaced apart from each other over the silicon substrate 20. For example, the silicon substrate 20 is a p-type substrate having an n-type well, and the first and the second source/drain regions 21 and 22 are regions formed by adding a p-type impurity to the n-type well.

The tunnel insulating film 30t, the charge storage layer CS1, the block insulating film 50, and the gate electrode 60 are disposed successively between the first and the second source/drain regions 21 and 22 above the silicon substrate 20.

The tunnel insulating film 30t is, for example, a silicon oxide film of 4 nm thickness. The charge storage layer CS1 has a nitride layer 30n (second or third layer), a film deposition layer 40t (first layer), and a nitrogen addition layer 40n (second or third layer) successively above the tunnel insulating film 30t. That is, the nitride layer 30n and the nitrogen addition layer 40n face the tunnel insulating film 30t and the block insulating film 50, respectively. Further, the thickness of the charge storage layer CS1 is, for example, 8 nm.

The nitrogen atom concentration in each of the nitride layer 30n and the nitrogen addition layer 40n is higher than the nitrogen atom concentration of the film deposition layer 40t. Preferably, the nitride layer 30n comprises silicon, nitrogen, and oxygen. Each of the film deposition layer 40t and the nitrogen addition layer 40n comprises silicon and nitrogen. Specifically, materials for the nitride layer 30n, the film deposition layer 40t, and the nitrogen addition layer 40n are, for example, SiNₓO_{y}, Si₃N₄, and Si₃N_{4+d} (d>0), respectively.

The block insulating film 50 is, for example, a silicon oxide film of 5 nm thickness. The gate electrode 60 is, for example, a polycrystal silicon film doped with an impurity.

Then, a method of manufacturing the non-volatile semiconductor memory device 101 is to be described. With reference to FIG. 2, the silicon substrate 20 is at first cleaned. Then, a thermal oxide film 30 (first insulating film) is formed over the silicon substrate 20 by thermal oxidation of the silicon substrate 20. The thickness of the thermal oxide film 30 is, for example, 4 nm.

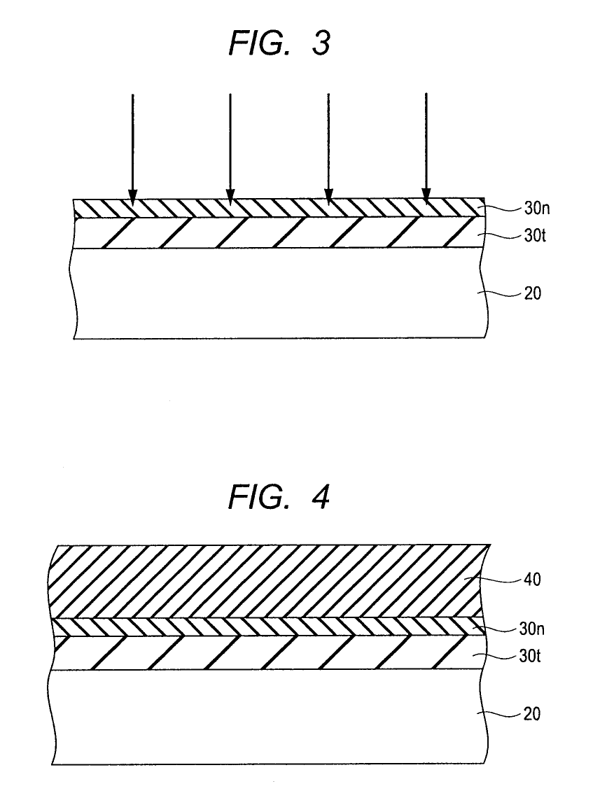

Referring to FIG. 2 and FIG. 3, nitrogen is added selectively on the side of the surface of the thermal oxide film 30 (upper side in FIG. 2). That is, nitrogen is not added to the thermal oxide film 30 on the side of the silicon substrate 20 but nitrogen is added selectively to the thermal oxide film 30 on the side of the surface. The thermal oxide film 30 is formed into a tunnel insulating film 30t and a nitride layer 30n on the side of the substrate 20 and on the side of the surface, respectively.

The nitrogen addition is preferably conducted by a method of providing a strong nitriding power and not giving physical or chemical damages to the tunnel insulating film 30t. Such a method includes, for example, a method of exposing the heated thermal oxide film 30 to nitrogen radicals.

Referring to FIG. 4, a film deposition film 40 is deposited over the nitride layer 30n. The film deposition layer 40 is a layer capable of storing charges and contained in the charge storage layer CS1 (FIG. 1). Specifically, the film deposition layer 40 is a silicon nitride film and, more specifically, it is a film comprising Si₃N₄. For the film deposition method, a vacuum thermal CVD (Chemical Vapor Deposition) method can be used.

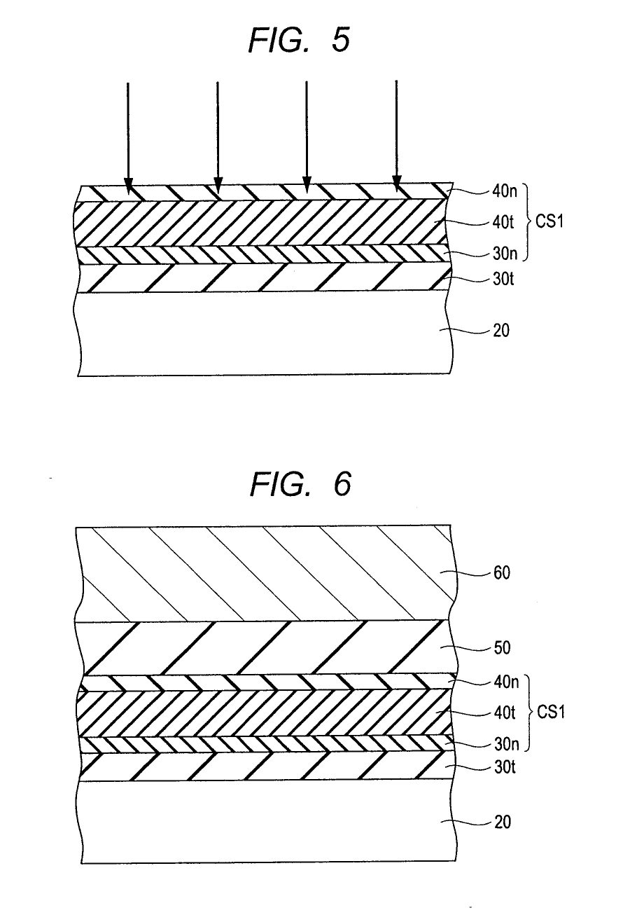

Referring to FIG. 4 and FIG. 5, nitrogen is added selectively to the film deposition layer 40 on the side of the surface. That is, nitrogen is not added to the film deposition layer 40 on the side of the nitride layer 30n but nitrogen is added selectively to the film deposition layer 40 on the side of the surface. Thus, the film deposition layer 40 is formed as the film deposition layer 40t and the nitrogen addition layer 40n on the side of the nitride layer 30n and on the side of the surface, respectively.

The nitrogen addition is preferably conducted by a method of providing a strong nitriding power and not giving physical or chemical damages to the film deposition layer 40t. Such a method includes, for example, a method of exposing the heated film deposition layer 40 to nitrogen radicals.

Referring to FIG. 6, a block insulating film 50 is formed by way of the nitrogen addition layer 40n above the film deposition layer 40t. As the film deposition method, a CVD method can be used.

Then, a gate electrode 60 is deposited over the block insulating film 50. As the film deposition method, a low pressure CVD method can be used.

Referring to FIG. 6 and FIG. 1, a laminate comprising the gate electrode 60, the block insulating film 50, the charge storage layer CS1, and the tunnel insulating film 30t is patterned. Then, impurity ions are implanted by an ion implantation method to the silicon substrate 20 using the laminate as a mask. Thus, the first and the second source/drain regions 21 and 22 are formed over the silicon substrate 20.

The non-volatile semiconductor memory device 101 is obtained as described above. Writing operation of the non-volatile semiconductor memory device 101 can be conducted, for example, by injecting electrons to the charge storage layer CS1 by Fowler-Nordheim tunneling. Further, erasing operation of the non-volatile semiconductor memory device 101 can be conducted, for example, by injecting holes to the charge storage layer CS1.

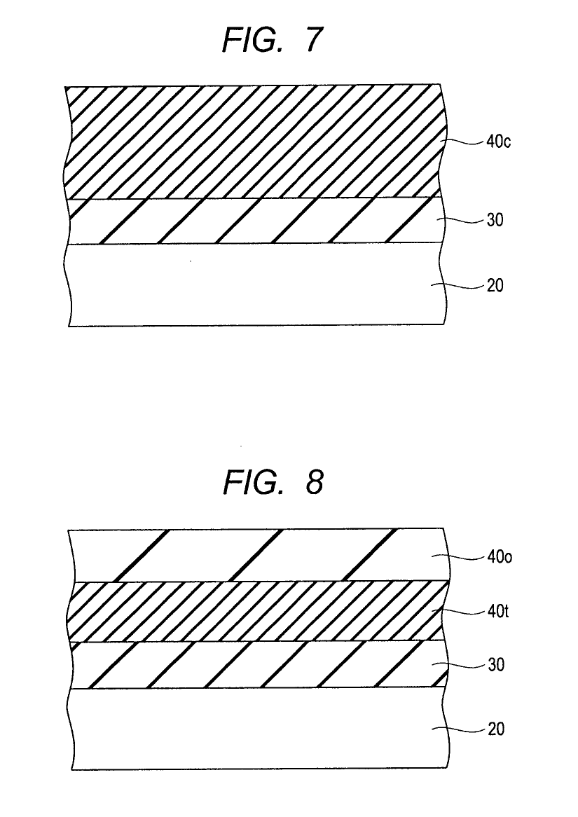

Then, a method of manufacturing a non-volatile semiconductor memory device of a comparative example is to be described. Referring to FIG. 7, a film deposition layer 40c is deposited over a thermal oxide film 30 by a CVD method. The film deposition layer 40c is, for example, a silicon nitride film of 14 nm thickness.

Referring to FIG. 7 and FIG. 8, a block insulating film 40o and a film deposition layer 40t are formed from the film disposition layer 40c by selective oxidation of the film disposition layer 40c on the side of the surface. The block insulating film 40o is an oxide layer formed by oxidation of the film deposition layer 40c, and the film deposition layer 40t is a portion of the film deposition layer 40c which is left unoxidized. Further, the thickness of the block insulating film 40o and the deposition layer 40t are, for example, 5 nm and 8 nm, respectively.

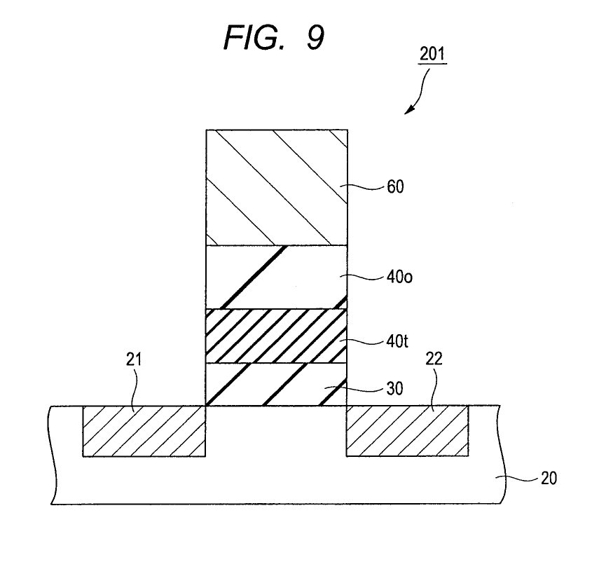

Referring to FIG. 9, a gate electrode 60 is deposited over the block insulating film 40o. Then, a non-volatile semiconductor memory device 201 of the comparative example is obtained by pattering and ion implantation.

The charge storage layer of the non-volatile semiconductor memory device 201 (FIG. 9) of the comparative example comprises a film deposition layer 40t. Accordingly, the efficiency of the charge storage layer that traps electrons is determined depending on the composition of the film deposition layer 40t.

On the contrary, according to the non-volatile semiconductor memory device 101 of this embodiment, the nitride layer 30n of the charge storage layer CS1 has a nitrogen atom concentration higher than the nitrogen atom concentration of the film deposition layer 40t, and nitride layer 30n faces the tunnel insulating film 30t. Accordingly, the charge storage layer CS1 has a nitrogen atom concentration higher than the nitrogen atom concentration of the film deposition layer 40t near the boundary with the tunnel insulating film 30t.

The vicinity of the boundary is a portion where electrons tend to be localized particularly compared with a position which situates sufficiently inside of the charge storage layer CS1. Accordingly, the charge storage layer CS1 has a particularly high nitrogen atom concentration at the portion where the electrons situate being localized particularly. As a result, electrons can be trapped more efficiently in the charge storage layer CS1 without increasing the thickness of the charge storage layer CS1.

Further, the nitrogen addition layer 40n of the charge storage layer CS1 has a nitrogen atom concentration higher than the nitrogen atom concentration of the film deposition layer 40t and the nitrogen addition layer 40n faces the block insulating film 50. Accordingly, the charge storage layer CS1 has a nitrogen atom concentration higher than the nitrogen atom concentration of the film deposition layer 40t near the boundary with the block insulating film 50.

The vicinity of the boundary is a portion where electrons tends to be localized particularly compared with the position which situates sufficiently inside of the charge storage layer CS1. Accordingly, the charge storage layer CS1 has a particularly high nitrogen atom concentration at the portion where the electrons are present being localized particularly. As a result, electrons can be trapped more efficiently in the charge storage layer CS1 without increasing the thickness of the charge storage layer CS1.

The electron trapping efficiency of the charge storage layer CS1 is improved sufficiently by the high nitrogen atom concentration in each of the nitride layer 30n and the nitrogen addition layer 40n as described above. Accordingly, the composition of the film deposition layer 40t of the charge storage layer CS1 can be selected without considering the improvement for the electron trapping efficiency but with a view point of other characteristics of the non-volatile semiconductor memory device 101. This can improve the degree of freedom for the design of materials in the non-volatile semiconductor memory device 101.

In the explanation described above, while it has been described for the method of using nitrogen radicals as the nitrogen addition method, the nitrogen addition method is not restricted only thereto. For the nitrogen addition method, a thermal nitridation process of using a gas containing the nitrogen element can also be used. As such a gas NH₃ or NO can be used, for instance.

### Second Embodiment

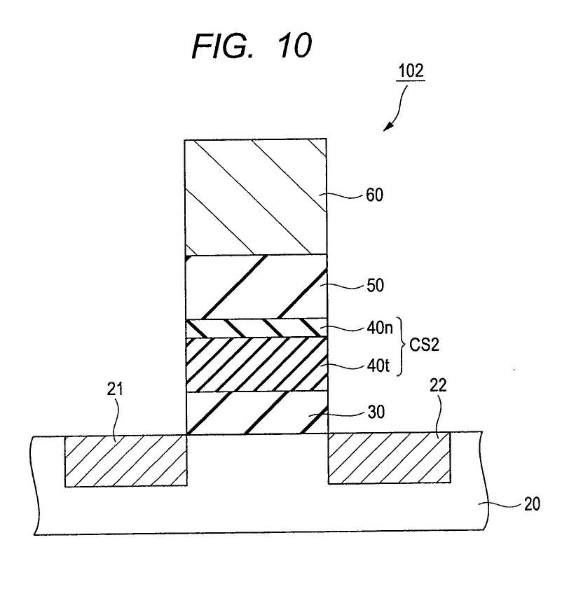

Referring to FIG. 10, a non-volatile semiconductor memory device 102 of this embodiment has a thermal oxide film 30 as a tunnel insulating film and a charge storage layer CS2 instead of the tunnel insulating film 30t and the charge storage layer CS1 of the non-volatile semiconductor memory device 101 (FIG. 1) in the first embodiment described above respectively. The charge storage layer CS2 has a film deposition layer 40t (first layer) and a nitrogen addition layer 40n (second layer) formed successively above the thermal oxide film 30.

Since other constituent elements than those described above are substantially identical with those of the first embodiment described above, identical or corresponding elements carry identical references, for which duplicate descriptions are to be omitted.

According to this embodiment, the nitrogen addition layer 40n of the charge storage layer CS2 has a nitrogen atom concentration higher than the nitrogen atom concentration of the film deposition layer 40t and the nitrogen addition layer 40n faces the block insulating film 50. Accordingly, the charge storage layer CS2 has a nitrogen atom concentration higher than the nitrogen atom concentration of the film deposition layer 40t near the boundary with the block insulating film 50.

The vicinity of the boundary is a portion where electrons tends to be localized particularly compared with the position which situates sufficiently inside of the charge storage layer CS2. Accordingly, the charge storage layer CS2 has a particularly high nitrogen atom concentration at the portion where the electrons are present being localized particularly. As a result, electrons can be trapped more efficiently in the charge storage layer CS2 without increasing the thickness of the charge storage layer CS2.

The electron trapping efficiency of the charge storage layer CS2 is improved sufficiently by the high nitrogen atom concentration of the nitrogen addition layer 30n as described above. Accordingly, the composition of the film deposition layer 40t of the charge storage layer CS2 can be selected without considering the improvement for the efficiency of trapping electrons but with a view point of other characteristics of the non-volatile semiconductor memory device 102. This can improve the degree of freedom for the design of materials in the non-volatile semiconductor memory device 102.

Further, different from the embodiment 1, it is not necessary to nitride the thermal oxide film 30. Accordingly, the manufacturing method is simplified more.

As has been described above, according to this embodiment, electrons can be trapped more efficiently in the charge storage layer CS2 without increasing the thickness of the charge storage layer CS2. The demonstration result thereof is to be described below while comparing the example of this embodiment with the comparative example.

For comparison with this embodiment, the non-volatile semiconductor memory device 201 (FIG. 9) of the comparative example was manufactured. In this case, the thickness of the film deposition layer 40t of the comparative example was made identical with that of the charge storage layer CS2 (FIG. 10) of this embodiment.

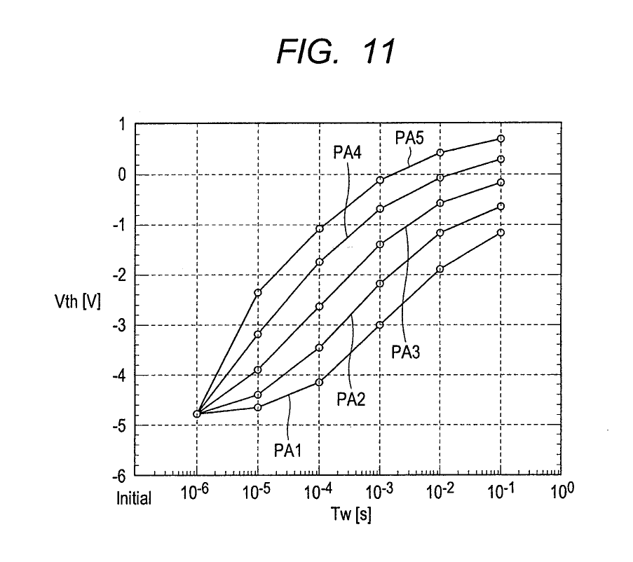

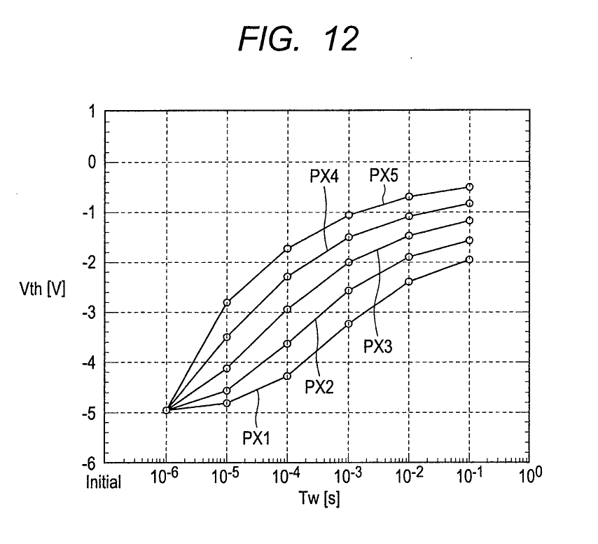

Referring to FIG. 11 and FIG. 12, respectively, a relation between a writing time Tw and a threshold voltage Vth after writing was measured for the non-volatile semiconductor memory device 102 of this embodiment (FIG. 10) and the non-volatile semiconductor memory device 201 (FIG. 9) of the comparative example. Plots PA1 to PA5 (FIG. 11) respectively show the result of measurement at the voltage of the gate electrode 60 (gate voltage) of 16V, 17V, 18V, 19V, and 20V in this embodiment. Further, plots PX 1 to PX 5 (FIG. 12) respectively show the result of measurement at the gate voltage of 16V, 17V, 18V, 19V, and 20V in the comparative example.

It was recognized from the result of the measurement that the threshold voltage Vth could be changed by a predetermined value in a shorter writing time Tw or at a lower gate voltage in the non-volatile semiconductor memory device 102 of this embodiment compared with the non-volatile semiconductor memory device 201 (FIG. 9) of the comparative example. That is, it was recognized that electrons could be trapped efficiently in the charge storage layer CS2 according to this embodiment.

In this embodiment, the gate electrode 60 was shaped as a square, a 100 μm on a side, the thickness of the thermal oxide film 30 was 4 nm, the thickness of the charge storage layer CS2 was 10 nm, and the thickness of the block insulating film 50 was 8 nm. Further, in the comparative example, the gate electrode 60 was shaped as a square, 100 μm on a side, the thickness of the tunnel insulating film (thermal oxide film 30) was 4 nm, the thickness of the charge storage layer (film deposition layer 40t) was 10 nm, and the thickness of the block insulating film 40o was 8 nm. Further, in the writing operation for the measurement described above, the silicon substrate 20 and the first and the second source/drain regions 21 and 22 were grounded to the earth. Further, the threshold voltage Vth at: Tw=10⁻⁶ in FIG. 11 and FIG. 12 was measured just after the initial erasing operation.

The initial erasing operation was conducted by injection of holes from the substrate. Specifically, the gate voltage, the well voltage, the substrate voltage, the source voltage, and the drain voltage were set to −9 V, +6 V, +6.5 V, 0 V, and 0 V, respectively, for 1 sec.

### Third Embodiment

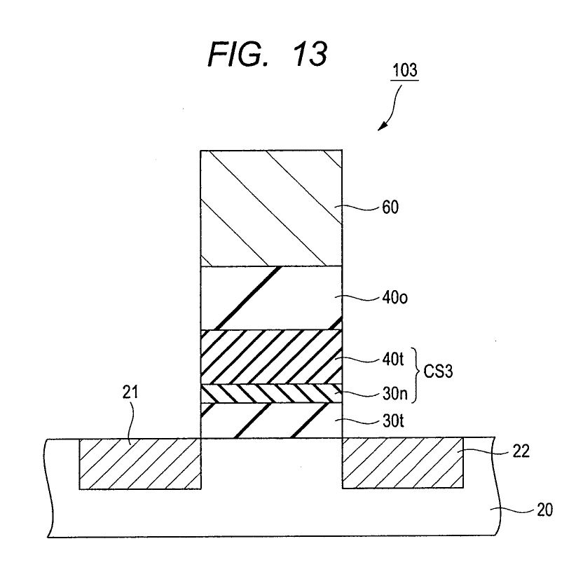

With reference to FIG. 13, a non-volatile semiconductor memory device 103 of this embodiment has a charge storage layer CS3 and a block insulating film 40o instead of the charge storage layer CS1 and the block insulating film 50 of the non-volatile semiconductor memory device 101 (FIG. 1) in the first embodiment described above respectively. The charge storage layer CS3 has a nitride layer 30n (second layer) and a film deposition layer 40t (first layer) formed successively above the tunnel insulating film 30t.

The film deposition layer 40t and the block insulating film 40o can be prepared by the same method as the manufacturing method for the comparative example described above (FIG. 7 and FIG. 8).

Since other constituent elements than those described above are substantially identical with those of the first embodiment described above, identical or corresponding elements carry same references for which duplicate descriptions are to be omitted.

According to this embodiment, the nitride layer 30n of the charge storage layer CS3 has a nitrogen atom concentration higher than the nitrogen atom concentration of the film deposition layer 40t and the nitride layer faces the tunnel insulating film 30t. Accordingly, the charge storage layer CS3 has a nitrogen atom concentration higher than the nitrogen atom concentration of the film deposition layer 40t near the boundary with the tunnel insulating film 30t.

The vicinity of the boundary is a portion where electrons tend to be localized particularly compared with the position which situates sufficiently inside of the charge storage layer CS3. Accordingly, the charge storage layer CS3 has a particularly high nitrogen atom concentration at the portion where the electrons are present being localized particularly. As a result, electrons can be trapped more efficiently in the charge storage layer CS3 without increasing the thickness of the charge storage layer CS3.

The electron trapping efficiency of the charge storage layer CS3 is improved sufficiently by the high nitrogen atom concentration of the nitrogen addition layer 30n as described above. Accordingly, the composition of the film deposition layer 40t of the charge storage layer CS3 can be selected without considering the improvement for the efficiency of trapping electrons but with a view point of other characteristics of the non-volatile semiconductor memory device 103. This can improve the degree of freedom for the design of materials in the non-volatile semiconductor memory device 103.

Further, different from the embodiment 1, it is not necessary to nitride the film deposition film 40t. Accordingly, the manufacturing method is simplified more.

Further, different from the first embodiment, the block insulating film 40o can be formed not by film deposition but by oxidation for the surface of the film deposition layer 40c (FIG. 7) as shown in FIG. 8.

As has been described above, according to this embodiment, electrons can be trapped more efficiently in the charge storage layer CS3 without increasing the thickness of the charge storage layer CS3. The demonstration result thereof is to be described below while comparing the example of this embodiment with the comparative example.

For comparison with this embodiment, a non-volatile semiconductor memory device 201 (FIG. 9) of the comparative example was manufactured. The thickness of the film deposition layer 40t of the comparative example was made identical with that of the charge storage layer CS3 (FIG. 13) of this embodiment.

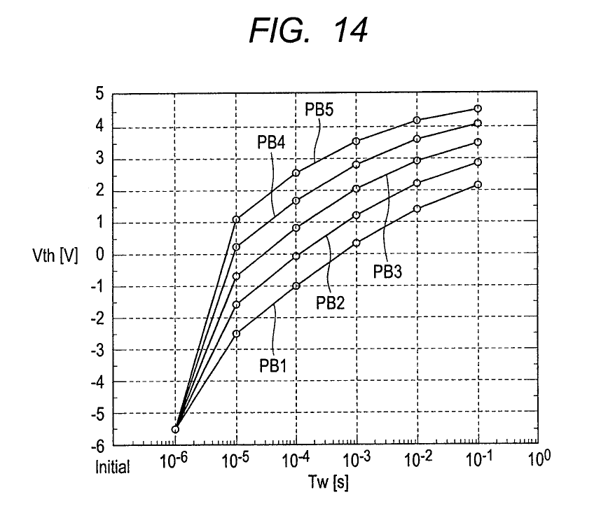

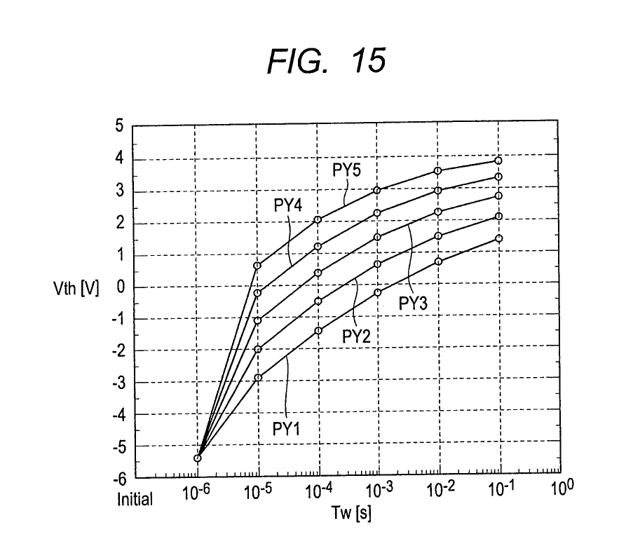

Referring to FIG. 14 and FIG. 15, respectively, a relation between a writing time Tw and a threshold voltage Vth after writing was measured for the non-volatile semiconductor memory device 103 of this embodiment (FIG. 13) and the non-volatile semiconductor memory device 201 (FIG. 9) of the comparative example. Plots PB1 to PB5 (FIG. 14) respectively show the result of measurement at the voltage of the gate electrode 60 (gate voltage) of 16 V, 17 V, 18 V, 19 V, and 20 V in this embodiment. Further, plots PY1 to PY5 (FIG. 15) respectively show the result of measurement at the gate voltage of 16 V, 17 V, 18 V, 19 V, and 20 V in the comparative example.

It was recognized from the result of the measurement that the threshold voltage Vth could be changed by a predetermined value in a shorter writing time Tw or at a lower gate voltage in the non-volatile semiconductor memory device 103 of this embodiment compared with the non-volatile semiconductor memory device 201 (FIG. 9) of the comparative example. That is, it was recognized that electrons could be trapped efficiently in the charge storage layer CS3 according to this embodiment.

In this embodiment (FIG. 13), the shape of the gate electrode 60 was shaped as a square, 100 μm on a side, the thickness of the tunnel insulating film 30t was 4 nm, the thickness of the charge storage layer CS3 was 8 nm, and the thickness of the block insulating film 40o was 6 nm. Further, in the comparative example, the gate electrode 60 was shaped as a square, 100 μm on a side, the thickness of the tunnel insulating film (thermal oxide film 30) was 4 nm, the thickness of the charge storage layer (film deposition layer 40t) was 8 nm, and the thickness of the block insulating film 40o was 6 nm.

Further, in the writing operation for the measurement described above, the silicon substrate 20 and the first and the second source/drain regions 21 and 22 were grounded to the earth. Further, the threshold voltage Vth at: Tw=10⁻⁶ in FIG. 14 and FIG. 15 was measured just after the initial erasing operation.

The initial erasing operation was conducted by injection of holes from the substrate. Specifically, the gate voltage, the well voltage, the substrate voltage, the source voltage, and the drain voltage were set to −9 V, +6 V, +6.5 V, 0 V, and 0 V, respectively, for 1 sec.

### Fourth Embodiment

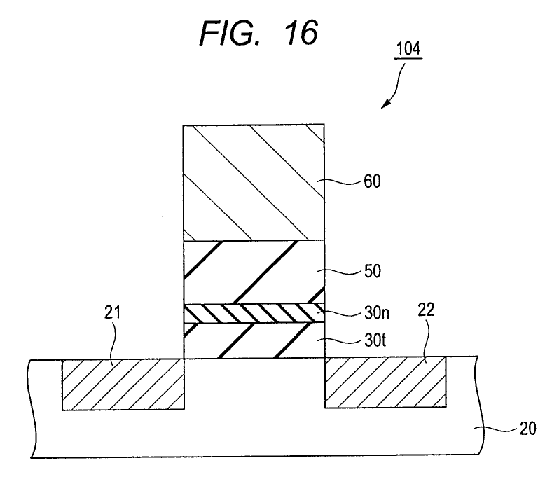

Referring to FIG. 16, a non-volatile semiconductor memory device 104 of this embodiment has a nitride layer 30n as the charge storage layer instead of the charge storage layer CS1 of the non-volatile semiconductor memory device 101 (FIG. 1) in the first embodiment described above.

Since other constitutional elements than those described above are substantially identical with those of the first embodiment described above, identical or corresponding elements carry same references for which duplicate descriptions are to be omitted.

According to this embodiment, the nitride layer 30n as the charge storage layer comprises the material formed by adding nitrogen to the material for the tunnel insulating film 30t. Accordingly, the charge storage layer (nitride layer 30n) is formed only by the element addition process without film deposition process. Thus, the charge storage layer can be formed further thinly and stably compared with the case of forming the charge storage layer by the film deposition process. That is, a charge storage layer capable of efficiently trapping electrons can be formed with a small thickness.

Further, different from the first embodiment, it is not necessary to form the film deposition layer 40 (FIG. 4). Accordingly, the manufacturing method is simplified more.

It should be construed that all embodiments disclosed herein are merely for examples and are not restrictive. The range of the present invention is shown not by the foregoing descriptions but by the description of the claims. It is intended to include all modifications within the meanings and the ranges equivalent with those of the claims.

The present invention is applicable with advantages, particularly, to a non-volatile semiconductor memory device having a charge storage layer and a manufacturing method thereof.

What is claimed is:

1. A non-volatile semiconductor memory device comprising:
a semiconductor substrate;
first and second source/drain regions disposed being spaced apart from each other over the semiconductor substrate; and
a tunnel insulating film, a charge storage layer, a block insulating film, and a gate electrode disposed successively between the first and the second source/drain regions above the semiconductor substrate,
wherein the charge storage layer includes a first layer having a first nitrogen atom concentration and a second layer having a second nitrogen atom concentration higher than the first nitrogen atom concentration, and the second layer faces one of the tunnel insulating film and the block insulating film.

2. A non-volatile semiconductor memory device according to claim 1,
wherein the second layer faces the tunnel insulating film, and
wherein the tunnel insulating film contains silicon and oxygen, and the second layer contains silicon, oxygen, and nitrogen.

3. A non-volatile semiconductor memory device according to claim 1,
wherein the second layer faces the block insulating film, and
wherein each of the first and the second layers contains silicon and nitrogen.

4. A non-volatile semiconductor memory device according claim 1,
wherein the charge storage layer further includes a third layer having a third nitrogen atom concentration higher than the first nitrogen atom concentration, and
wherein the third layer faces the other of the tunnel insulating film and the block insulating film.

5. A non-volatile semiconductor memory device comprising:
a semiconductor substrate;
first and second source/drain regions disposed being spaced apart from each other over the semiconductor substrate; and
a tunnel insulating film, a charge storage layer, a block insulating film, and a gate electrode disposed successively between the first and the second source/drain regions over the semiconductor substrate,
wherein the charge storage layer comprises a material formed by adding at least nitrogen to the material for the tunnel insulating film.

6. A non-volatile semiconductor memory device according to claim 5,
wherein the tunnel insulating film comprises silicon oxide.

7. A method of manufacturing a non-volatile semiconductor memory device comprising the steps of:
forming a first insulating film over a semiconductor substrate,
adding nitrogen selectively to the first insulating film on the side of the surface for forming the first insulating film on the side of the semiconductor substrate as a tunnel insulating film and for forming the first insulating film on the side of the surface as a nitrogen addition layer contained in the charge storage layer,
depositing a film deposition layer contained in the charge storage layer over the nitrogen addition layer,
forming a block insulating film over the film deposition layer, and
forming a gate electrode over the block insulating film.

8. A method of manufacturing a non-volatile semiconductor memory device according to claim 7,
wherein the step of adding nitrogen is conducted by exposing the heated first insulating film to nitrogen radicals.

9. A method of manufacturing a non-volatile semiconductor memory device comprising the steps of:
forming a tunnel insulating film over a semiconductor substrate; and
forming a charge storage layer over the tunnel insulating film,
wherein the step of forming the charge storage layer includes the steps of:
depositing a film deposition layer over the tunnel insulating film; and
adding nitrogen selectively to the film deposition layer on the side of the surface and, further, including the steps of:
forming a block insulating film over the charge storage layer; and
forming a gate electrode over the block insulating film.

10. A method of manufacturing a non-volatile semiconductor memory device according to claim 9,
wherein the step of adding nitrogen is conducted by exposing the heated film deposition layer to nitrogen radials.

11. A method of manufacturing a non-volatile semiconductor memory device comprising the steps of:
forming a first insulating film over a semiconductor substrate;
adding nitrogen selectively to the first insulating film on the side of the surface for forming the first insulating film on the side of the substrate as a tunnel insulating film and for forming the first insulating film on the side of the surface as a charge storage layer;
forming a block insulating film that faces the charge storage layer; and
forming a gate electrode over the block insulating film.

12. A method of manufacturing a non-volatile semiconductor memory device according to claim 11,
wherein the step of adding nitrogen is conducted by exposing the heated first insulating film to nitrogen radicals.
